(19) United States
(12) Patent Application Publication
(10) Pub. No.: US 2020/0403567 A1
(43) Pub. Date: Dec. 24, 2020

(54) PHOTOVOLTAlC MODULE

(71) Applicant: NEWSOUTH INNOVATIONS PTY LIMITED, Sydney, New South Wales (AU)

(72) Inventors: Martin Andrew GREEN, Bronte, New South Wales (AU); Yajie Jessica JIANG, Caringbah, New South Wales (AU); Mark KEEVERS, Maroubra, New South Wales (AU); Nicholas EKINS-DAUKES, Kensington, New South Wales (AU); Zibo ZHOU, Rhodes, New South Wales (AU)

(21) Appl. No.: 16/975,377

(22) PCT Filed: Feb. 27, 2019
(86) PCT No.: PCT/AU2019/050168

§ 371 Date: Aug. 24, 2020

(30) Foreign Application Priority Data
Feb. 27, 2018 (AU) 2018900640

(51) Int. Cl. H02S 40/42; H01L 31/048

(52) U.S. Cl. CPC H02S 40/42; F28F 2245/06; H01L 31/0488

(57) ABSTRACT

The present disclosure provides a photovoltaic module, which comprises a photon absorbing material comprising a solar cell; The photovoltaic module also comprises a glass material positioned within a plane and being positioned over the photon absorbing material such that in use light is incident on the glass material and the glass material transmits light towards the photon absorbing material, the glass material having a front surface facing away from the photon absorbing material. The front surface of the glass material has a shape which is profiled such that the emittance of infrared light from the front surface of the glass material is increased compared to that of a flat front surface, the emittance of the infrared light being associated with absorbance of infrared light that is incident upon the front surface. A rear backing sheet of the photovoltaic module may have a shape that is profiled in a corresponding manner.

### TECHNICAL FIELD OF THE INVENTION

The present invention relates to a photovoltaic module.

### BACKGROUND OF THE INVENTION

Photovoltaic modules are now used for various applications. It is known that the conversion efficiency of photovoltaic modules is adversely affected if the temperature of the photovoltaic modules increases. Photovoltaic modules often operate in bright sunlight, typically 20-30° C. above ambient temperature. This not only reduces the energy production of a photovoltaic module by 0.4-0.5% (relative) for every degree increase in temperature (up to 15% for a 30° C. increase in temperature), but also accelerates all known degradation processes and reduces the lifespan of the photovoltaic module below a lifespan that is otherwise achievable.

In addition, photovoltaic modules typically degrade 0.5% (relative) in output for each year in the field, with photovoltaic modules normally warranted to be above 80% of their initial rating after 25 years of field exposure. Further, long time testing of specific degradation modes suggest degradation rates approximately double for every 10° C. increase in temperature. This suggests that photovoltaic modules operating at a temperature lower than the above-mentioned typical operating temperature could not only increase their energy production, but could also have a reduced degradation and could consequently be used for extended periods of time than otherwise possible.

### SUMMARY OF THE INVENTION

In accordance with a first aspect of the present invention there is provided a photovoltaic module comprising:

a photon absorbing material comprising a solar cell; and

a glass material being positioned within a plane and being position over the photon absorbing material such that in use light is incident on the glass material and the glass material transmits light towards the photon absorbing material, the glass material having a front surface facing away from the photon absorbing material;

wherein the front surface of the glass material has a shape which is profiled such that the emittance of infrared light from the front surface of the glass material is increased compared to that of a flat front surface, the emittance of the infrared light being associated with absorbance of infrared light that is incident upon the front surface within a predefined angular range relative to a surface normal of the plane in which the glass material is positioned.

The defined shape of the front surface of the glass material in use increases an amount of thermal energy radiated by the glass material particularly at oblique angles and consequently contributes to reducing the operating temperature of the photovoltaic module.

In one specific embodiment the front surface of the glass material has a shape which is profiled such that the emittance of infrared radiation is increased compared to that of a flat front surface, the emittance of the infrared radiation being associated with absorption of light that is incident at oblique angles relative to a surface normal of the plane in which the glass material is positioned.

The front surface of the glass material may comprise structures, such as inverted pyramids or any other suitable type of recesses or projections. The recesses or projections may have surfaces that recess or project, respectively, from the plane in which the glass material is positioned an angle within the range of less than 90°-80°, 80°-70°, 70°-60°, 60°-50°, 50°-40°, 40°-30°, 30°-20°, 20° to 10° or less than 10°. Smaller angles are advantageous for cleaning purposes and preventing accumulation of particles, whereas larger angles have optical advantages.

The photovoltaic module may also comprise a rear backing sheet positioned such that the photon absorbing material is located between the glass material and the rear backing sheet, the rear backing sheet having a rear surface facing away from the photon absorbing material and having a shape which is profiled such that the emittance of infrared radiation is increased compared to that of a flat rear surface, the emittance being associated with absorption of infrared light that is incident upon the rear surface of the rear backing sheet within a predefined angular range relative to a surface normal of a plane in which the rear backing sheet is positioned.

The defined shape of the rear surface of the backing sheet in use increases an amount of thermal energy radiated by the rear backing sheet particularly at oblique angles and consequently contributes to reducing the operating temperature of the photovoltaic module.

The rear backing sheet may be formed from a glass material.

The rear surface of the backing sheet may comprise structures, such as inverted pyramids or any other suitable type of recesses or projections. The recesses or projections may have surfaces that recess or project, respectively, from the plane in which the glass material is positioned an angle within the range of less than 90°-80°, 80°-70°, 70°-60°, 60°-50°, 50°-40°, 40°-30°, 30°-20°, 20° to 10° or less than 10°.

In accordance with a second aspect the present invention provides a photovoltaic module, comprising:

a glass material;

a photon absorbing material comprising a solar cell; and

a rear backing sheet positioned such that the photon absorbing material is located between the glass material and the rear backing sheet;

wherein the rear backing sheet has a rear surface facing away from the photon absorbing material, the rear surface having a shape which is profiled such that the emittance of infrared radiation is increased compared to that of a flat rear surface, the emittance being associated with absorption of infrared light that is incident upon the rear surface of the rear backing sheet within a predefined angular range relative to a surface normal of a plane in which the rear backing sheet is positioned.

In one specific embodiment the rear surface of the rear backing has a shape which is profiled such that the emittance of infrared radiation is increased compared to that of a flat rear surface, the emittance of the infrared radiation being associated with absorption of light that is incident at oblique angles relative to a surface normal of the plane in which the rear backing sheet is positioned.

The rear surface of the backing sheet may also comprise structures, such as inverted pyramids or any other suitable type of recesses or projections. The recesses or projections may have surfaces that recess or project, respectively, from the plane in which the glass material is positioned an angle within the range of less than 90°-80°, 80°-70°, 70°-60°, 60°-50°, 50°-40°, 40°-30°, 30°-20°, 20° to 10° or less than 10°.

The rear backing sheet may be formed from a glass material.

### BRIEF DESCRIPTION OF THE DRAWINGS

Embodiments of the invention will now be described, by way of example, with reference to the accompanying drawings in which:

FIG. 1 is a schematic representation of a photovoltaic module in accordance with an embodiment of the present invention;

FIG. 2 is a graph showing the calculated emissivity as a function of angle to the perpendicular;

FIG. 3 is a schematic representation of a component of a photovoltaic module in accordance with an embodiment of the present invention; and

FIG. 4 is a schematic representation of a component of a photovoltaic module in accordance with another embodiment of the present invention.

### DETAILED DESCRIPTION OF EMBODIMENTS

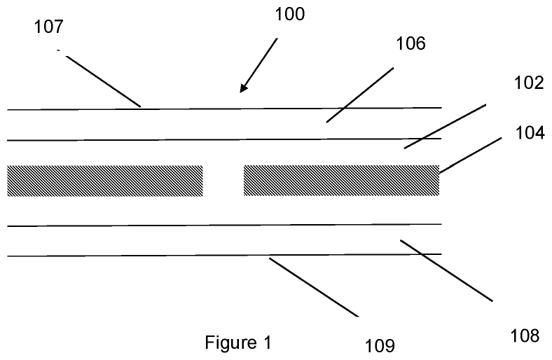

A photovoltaic module in accordance with embodiments of the present invention is now described. FIG. 1 schematically illustrates components of a photovoltaic module 100. The photovoltaic module 100 comprises a transparent encapsulant material 102 that encapsulates a solar cell 104, which in use absorb incident photons for electricity generation.

The photovoltaic module further comprises a glass material 106 that has a front surface 107. The photovoltaic module also comprises a back sheet 108 having a rear surface 109.

A person skilled in the art will appreciate that the photovoltaic module may comprise additional components which are omitted for clarity.

The front surface 107 of the glass material 106 has a shape which is profiled such that the emittance of infrared light from the front surface 107 of the glass material 106 is increased compared to that of a flat front surface. The emittance of the infrared light is associated with absorbance of infrared light that is incident upon the front surface 107 within a predefined angular range relative to a surface normal of the plane in which the glass material 106 is positioned.

In one specific embodiment predefined angular range is an angular range of oblique angles.

The front surface may comprise structures, such as inverted pyramids or any other suitable type of recesses or projections. The recesses or projections may have surfaces that recess or project, respectively, from the plane in which the glass material is positioned at suitable oblique angles. As described above, smaller angles are advantageous for cleaning purposes and preventing accumulation of particles, whereas larger angles have optical advantages.

The rear surface 109 of the rear sheet 108 may have a shape that is profiled in the same manner as the front surface 107 of the glass material 106.

The profiled front surface 107 and the profiled rear surface 109 will be described in more detail further below.

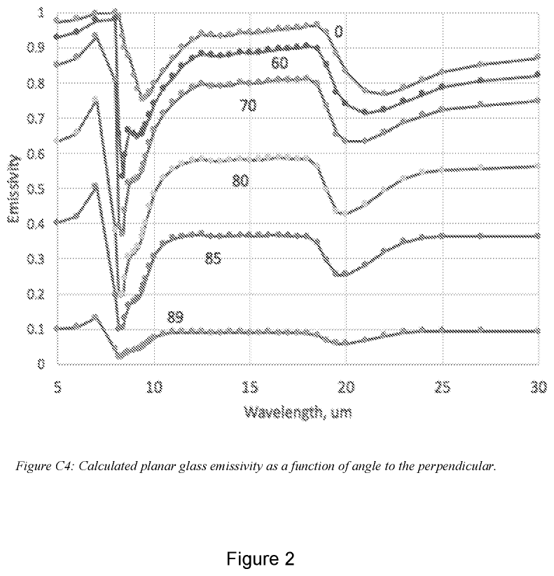

Turning now to FIG. 2, there are calculations of the glass emissivity for different angles relative to a surface normal of planar glass material. The calculation was performed for glass material, such as low-iron soda-lime glass, that absorbs incident electromagnetic radiation through stretched Si—O and Si—Si bonds and bent Si—O—Si bonds, at wavelengths in the proximity of 9 microns, 12 microns and 21 microns.

For example, the upper curve (showing the emission along the surface normal) of the graph shown in FIG. 2 shows “dips” at wavelengths of approximately 9 microns and 21 microns, and a smaller dip at 12 microns, corresponding absorption associated with the above-mentioned bonds.

In particular the absorption at wavelengths of 12 microns and 21 microns by the glass material reduces the thermal emission from the glass and results in an increase in temperature of the photovoltaic module and consequently is unwanted (these strong absorption bands change the refractive index in the vicinity of these absorption bands, which in turn increases reflection and hence decreases absorption and emissivity in the vicinity of the absorption bands).

The calculated emissivity illustrated in FIG. 2 shows the angular dependency of the emissivity. The emissivity decreases for increasing angles relative to the perpendicular.

The front surface 107 in accordance with embodiments of the present invention is profiled in a manner such that the emissivity especially at oblique angles is increased. The recesses or projections of the front surface 107 have surfaces that recess or project, respectively, as angles at which the emittance of infrared radiation (and associated absorption of incident infrared radiation) is increased compared to that of a flat front surface, which reduces heating of the photovoltaic module.

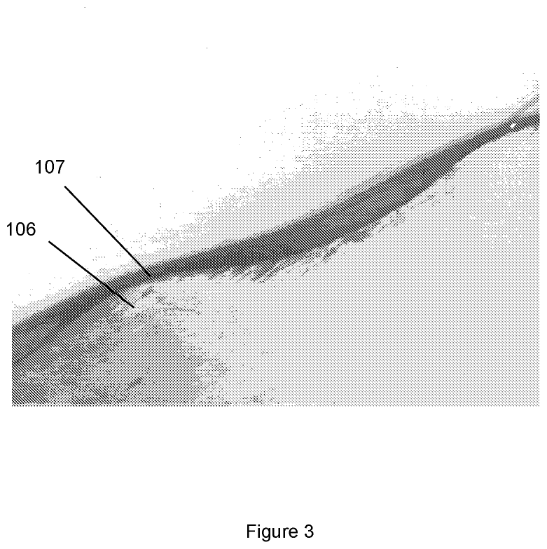

FIG. 3 is a schematic illustration of a portion of the front surface of the glass material 106. The front surface 107 of the glass material 106 shown in FIG. 3 has a profiled shape, which is arranged to avoid or reduce reflection of at least a portion of electromagnetic radiation incident upon the glass material and which would otherwise be reflected if the front surface were flat, particularly for oblique angles of incidence. In this example, the front surface has an undulating surface profile and the undulations project at an angle of less than 30° from a direction determined by a general orientation of the front surface 107. Decreasing the glass reflection, particularly at oblique angles, increases the thermal energy emission of the glass.

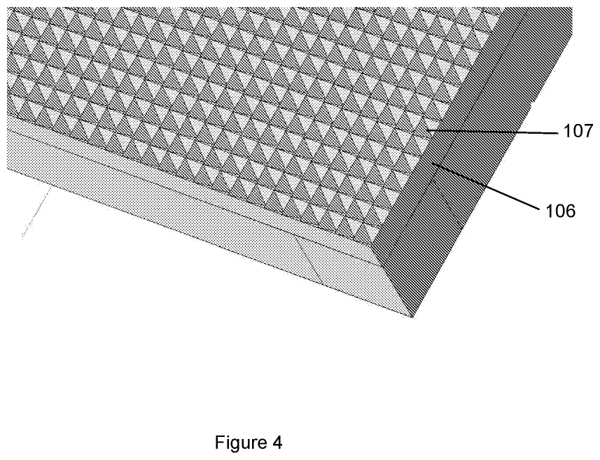

FIG. 4 shows a portion of a macro-structured front surface of a glass material 106 in accordance with a further embodiment of the present invention. In this example the front surface comprises a pattern of inverted pyramids.

A person skilled in the art will appreciate that the front surface may alternatively have a shape that is profiled in any other suitable manner that increases emissivity of infrared radiation at oblique angles.

In the above-illustrated examples the front surface 107 of the glass material 106 is macro-textured. Alternatively or additionally, the rear surface 109 of the back sheet 108 may be macro-textured and profiled in the same manner as the front surface 107 of the glass material 106 to increase loss of thermal radiation through the back sheet 108. The back sheet 108 may also be formed from glass.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A photovoltaic module, comprising:
a photon absorbing material comprising a solar cell; and
a glass material being positioned within a plane and being position over the photon absorbing material such that in use light is incident on the glass material and the glass material transmits light towards the photon absorbing material, the glass material having a front surface facing away from the photon absorbing material;
wherein the front surface of the glass material has a shape which is profiled such that the emittance of infrared light from the front surface of the glass material is increased compared to that of a flat front surface, the emittance of the infrared light being associated with absorbance of infrared light that is incident upon the front surface within a predefined angular range relative to a surface normal of the plane in which the glass material is positioned.

2. The photovoltaic module of claim 1 wherein the front surface of the glass material has a shape which is profiled such that the emittance of infrared radiation is increased compared to that of a flat front surface, the emittance of the infrared radiation being associated with absorption of light that is incident at oblique angles relative to a surface normal of the plane in which the glass material is positioned.

3. The photovoltaic module of claim 1 comprising recesses or projections which have surfaces that recess or project, respectively, from the plane in which the glass material is positioned at an angle within the range of less than 90°-80°, 80°-70° or 70°-60°.

4. The photovoltaic module of claim 1 comprising recesses or projections which have surfaces that recess or project, respectively, from the plane in which the glass material is positioned at an angle within the range of 60°-50° 50°-40°, or 40°-30°.

5. The photovoltaic module of claim 1 comprising recesses or projections which have surfaces that recess or project, respectively, from the plane in which the glass material is positioned at an angle within the range of 30°-20°, 20° to 10° or less than 10°.

6. The photovoltaic module of claim 1 further comprising a rear backing sheet positioned such that the photon absorbing material is located between the glass material and the rear backing sheet, the rear backing sheet having a rear surface facing away from the photon absorbing material and having a shape which is profiled such that the emittance of infrared radiation is increased compared to that of a flat rear surface, the emittance being associated with absorption of infrared light that is incident upon the rear surface of the rear backing sheet.

7. The photovoltaic module of claim 6 wherein the rear surface of the rear backing sheet has a shape which is profiled such that the emittance of infrared radiation is increased compared to that of a flat rear backing sheet, the emittance of the infrared radiation being associated with absorption of light that is incident at oblique angles relative to a surface normal of the plane in which the rear backing sheet is positioned.

8. The photovoltaic module of claim 6 wherein the rear backing sheet is formed from a glass material.

9. A photovoltaic module comprising:
a glass material;
a photon absorbing material for absorbing received electromagnetic radiation, the photon absorbing material comprising a solar cell; and
a rear backing sheet positioned such that the photon absorbing material is located between the glass material and the rear backing sheet;
wherein the rear backing sheet has a rear surface facing away from the photon absorbing material, the rear surface having a shape which is profiled such that
the emittance of infrared radiation is increased compared to a that of a flat rear surface, the emittance of the infrared light being associated with absorbance of infrared light that is incident upon the rear surface of the rear backing sheet within a predefined angular range relative to a surface normal of the plane in which the glass material is positioned.

10. The photovoltaic module of claim 8 wherein the rear surface of the rear backing sheet has a shape which is profiled such that the emittance of infrared radiation is increased compared to that of a flat rear backing sheet, the emittance of the infrared radiation being associated with absorption of light that is incident at oblique angles relative to a surface normal of the plane in which the rear backing sheet is positioned.

11. The photovoltaic module of claim 9 comprising recesses or projections which have surfaces that recess or project, respectively, from the plane in which the glass material is positioned at an angle within the range of less than 90°-80°, 80°-70°, 70°-60° or 60°-50°.

12. The photovoltaic module of claim 9 comprising recesses or projections which have surfaces that recess or project, respectively, from the plane in which the glass material is positioned at an angle within the range of 60°-50°, 50°-40°, 40°-30°.

13. The photovoltaic module of claim 9 comprising recesses or projections which have surfaces that recess or project, respectively, from the plane in which the glass material is positioned at an angle within the range of 30°-20°, 20° to 10° or less than 10°.

14. The photovoltaic module of claim 9 wherein the rear backing sheet is formed from a glass material.
